(19) United States
(12) Patent Application Publication
(10) Pub. No.: US 2013/0160808 A1
(43) Pub. Date: Jun. 27, 2013

(54) THERMOELECTRIC GENERATING APPARATUS AND MODULE

(71) Applicants: Chung-Yen Hsu, Taoyuan County (TW); Sheng-Liang Li, Taipei City (TW)

(72) Inventors: Chung-Yen Hsu, Taoyuan County (TW); Sheng-Liang Li, Taipei City (TW)

(73) Assignee: Industrial Technology Research Institute, Hsinchu (TW)

(21) Appl. No.: 13/430,660

(22) Filed: Mar. 26, 2012

(30) Foreign Application Priority Data
Dec. 26, 2011 (TW) 100148648

(51) Int. Cl. H01L 35/32

(52) U.S. Cl. 136/224

(57) ABSTRACT

A thermoelectric generating apparatus is provided which includes a first and a second thermoelectric (TE) devices. The first TE device and the second TE device have an electrical junction surface that is an interdigitated junction interface. The Seebeck coefficient of the first TE device is more than that of the second TE device. The first TE device includes a first extended portion, and the second TE device includes a second extended portion. The first extended portion is electrically connected with a first power output end with a first contact surface formed therebetween, and the area of the electrical junction surface is larger than that of the first contact surface. The second extended portion is electrically connected with a second power output end with a second contact surface formed therebetween, and the area of the electrical junction surface is larger than that of the second contact surface.

### CROSS-REFERENCE TO RELATED APPLICATION

This application claims the priority benefit of Taiwan application serial no. 100148648, filed on Dec. 26, 2011. The entirety of the above-mentioned patent application is hereby incorporated by reference herein and made a part of this specification.

### TECHNICAL FIELD

The disclosure relates to a thermoelectric generating apparatus and a thermoelectric generating module which are widely applicable in various fields.

### BACKGROUND

In the conventional application of thermoelectricity, whether a substance is a good thermoelectric material may be basically judged by its figure of merit (ZT value), which is essentially related to the Seebeck coefficient, the electrical conductivity, and the thermal conductivity of the substance. These three parameters also affect the thermoelectric property of a material and determine whether the material can be used in thermoelectric application. The higher the ZT value, the more significant the thermoelectric effect. The ZT value is given by following equation.

$$ZT = \frac{{α}^{2} σ}{k} T$$

In this equation, α, σ, k and T are the Seebeck coefficient, the electrical conductivity, the thermal conductivity coefficient, and the absolute temperature, respectively. In light of above equation, it may be seen that, in addition to a desirable Seebeck coefficient, a good thermoelectric material further requires a high electrical conductivity and a low thermal conductivity coefficient.

In general, the electrical conductivity and thermal conductivity of a material are in positive correlation. Thus, it maybe difficult to find an ordinary material exhibiting both a high electrical conductivity and a low thermal conductivity coefficient. As a result, the ZT value can hardly be effectively promoted. Accordingly, the control to the electrical conductivity and thermal conductivity of a material has become a critical point of improving the thermoelectric performance. For example, the Seebeck coefficient of p-type silicon is 2.8 times higher than that of the commonly used Bi₂TE₃, but the thermal conductivity of p-type silicon is 74 times higher than that of Bi₂TE₃. This explains the reason why silicon with a high Seebeck coefficient is rarely used as thermoelectric material.

To sum up, it is known that the primary object of development in thermoelectric materials is to lower the thermal conductivity coefficient of a material while maintaining the electrical conductivity thereof above a certain limit, or to establish equivalent design factors to fulfil these requirements.

A conventional thermoelectric generating apparatus is shown in FIG. 1. The cold end and hot end are the upper end and the lower end of the thin thermoelectric device 100, respectively. The thermal conductive characteristics of the cold end and the hot end may affect each other because the path of thermal conduction is short. When a conventional thermoelectric generating apparatus is used, this problem gives rise to a need of a heat dissipating device (not shown) such as a heat sink, fans, or a water-cooling system for cooling the cold end so as to maintain the temperature difference between the cold end and the hot end. This operating manner is complex and may limit the application scope. A further issue of this operating manner is that the heat dissipating device at the cold end may accelerate the heat dissipation of the hot end. To maintain the temperature difference, the hot end has to be replenished with corresponding amount of heat as heat is dissipated at the cold end. In case of the thermal conductivity coefficient of a material is not sufficiently low in comparison to the power factor thereof, which is a common situation before the discovery of a high ZT material, the device performance may be unsatisfactory because heat from a heat source may comparatively loss.

It is known from U.S. Pat. No. 6,060,657 that a super-lattice film with multi-quantum well can be fabricated by nanotechnology to reduce the thermal conductivity.

Also, a bulk thermoelectric material is shaped into a cone in U.S. Pat. No. 6,384,312 so as to form a minute contact point at the contact interface with the electrode to limit the amount of reflowed heat at the contact interface.

### SUMMARY

The disclosure introduces a thermoelectric generating apparatus including a first thermoelectric device and a second thermoelectric device. The second thermoelectric device has an electrical junction interface with the first thermoelectric device, wherein the electrical junction surface is an interdigitated junction interface, and the Seebeck coefficient of the first thermoelectric device is larger than the Seebeck coefficient of the second thermoelectric device. The first thermoelectric device includes a first extended portion. The second thermoelectric device includes a second extended portion. The first extended portion is electrically connected to a first power output end with a first contact interface formed therebetween, and the area of the electrical junction interface is larger than the area of the first contact interface. The second extended portion is electrically connected to a second power output end with a second contact interface formed therebetween, and the area of the electrical junction interface is larger than the area of the second contact interface.

The disclosure further introduces a thermoelectric generating apparatus including a first thermoelectric device, a second thermoelectric device, a first output circuit, a second output circuit, and at least one compensating thermoelectric structure. The second thermoelectric device has a first electrical junction interface with the first thermoelectric device, wherein the Seebeck coefficient of the first thermoelectric device is larger than the Seebeck coefficient of the second thermoelectric device. The first output circuit is connected to the first thermoelectric device with a first contact interface formed therebetween, wherein the area of the first electrical junction interface is larger than the area of the first contact interface. The second output circuit is connected to the second thermoelectric device with a second contact interface formed therebetween, wherein the area of the first electrical junction interface is larger than the area of the second contact interface. The compensating thermoelectric structure is disposed between the first output circuit and the second output circuit.

Still further, the disclosure introduces a thermoelectric generating module including a plurality of the thermoelectric generating apparatuses described above.

Several exemplary embodiments accompanied with figures are described in detail below to further describe the disclosure in details.

### BRIEF DESCRIPTION OF THE DRAWINGS

The accompanying drawings are comprised to provide further understanding, and are incorporated in and constitute a part of this specification. The drawings illustrate exemplary embodiments and, together with the description, serve to explain the principles of the disclosure.

FIG. 1 is a schematic diagram of a conventional thermoelectric generating apparatus.

FIG. 2 is a schematic diagram illustrating the principle of the disclosure.

FIGS. 3A to 3C illustrate the temperature profiles with different heating conditions respectively.

FIG. 4 is a schematic diagram illustrating the relationship between the thermoelectric voltage and the junction interface according to the disclosure.

FIG. 5 is a sectional view of a thermoelectric generating apparatus according to the first embodiment of the disclosure.

FIG. 6A is a sectional view of a modified example of the heat source of the first embodiment.

FIG. 6B is a sectional view of a modified example of the electrical junction interface of the first embodiment.

FIG. 6C is a sectional view of a modified example of the power output end of the first embodiment.

FIG. 6D is a sectional view of a modified example of the extended portion of the first embodiment.

FIG. 7 is a schematic diagram of a thermoelectric generating module according to the second embodiment of the disclosure.

FIG. 8A is a top view of a thermoelectric generating apparatus according to the third embodiment of the disclosure.

FIG. 8B is a sectional view along the line B-B′ in FIG. 8A.

FIG. 9A is a top view of a thermoelectric generating apparatus according to the fourth embodiment of the disclosure.

FIG. 9B is a sectional view along the line B-B′ in FIG. 9A.

FIG. 10 is a circuit diagram of a thermoelectric generating apparatus equipped with a compensating thermoelectric structure according to the disclosure.

FIG. 11A is a sectional view of the first type of the thermoelectric generating apparatus according to the fifth embodiment of the disclosure.

FIG. 11B is a sectional view of the second type of the thermoelectric generating apparatus according to the fifth embodiment of the disclosure.

FIG. 11C is a sectional view of the third type of the thermoelectric generating apparatus according to the fifth embodiment of the disclosure.

FIG. 11D is a sectional view of the fourth type of the thermoelectric generating apparatus according to the fifth embodiment of the disclosure.

FIG. 12 is a simplified diagram of the thermoelectric generating apparatus of a simulation result.

FIG. 13 is the electrical characteristic curves of a simulation result.

FIG. 14 is the electrical characteristic curves of a simulation result with different input power of the heat source.

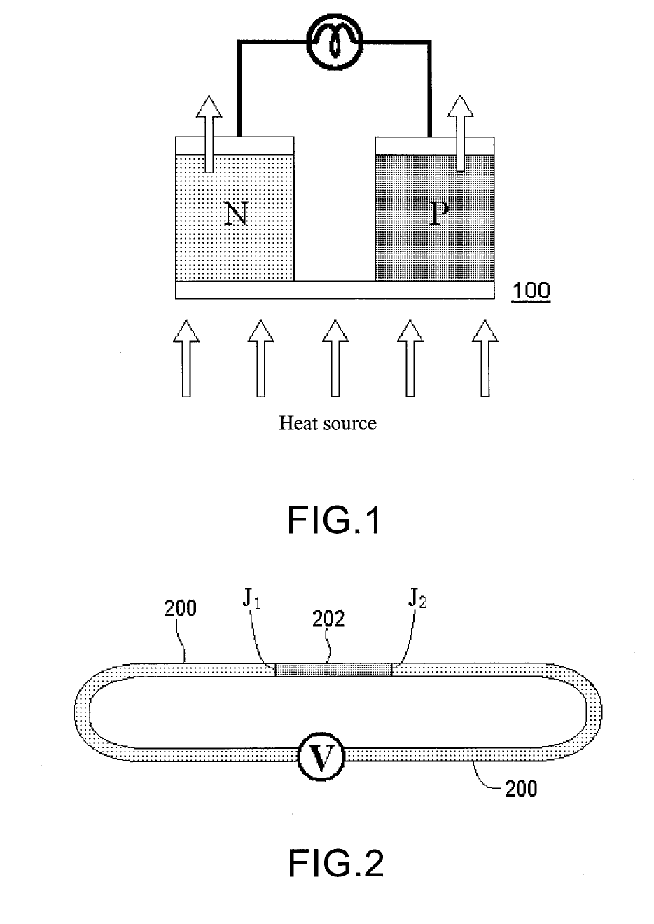

### DETAILED DESCRIPTION OF DISCLOSED EMBODIMENTS

The concept of the disclosure is different from that of some conventional thermoelectric devices and will be described in detail as follows.

Based on the working principle of thermoelectric devices, two different types of materials (200 and 202) are connected in series as shown in FIG. 2. The temperatures of the junction interfaces J₁ and J₂ are locally controlled and measured. The material 200 has a larger Seebeck coefficient while material 202 has a smaller one. When the junction interface J₁ is supplied with heat by a heat source, the junction interfaces J₁ and J₂ have two different temperatures T₁ and T₂, respectively.

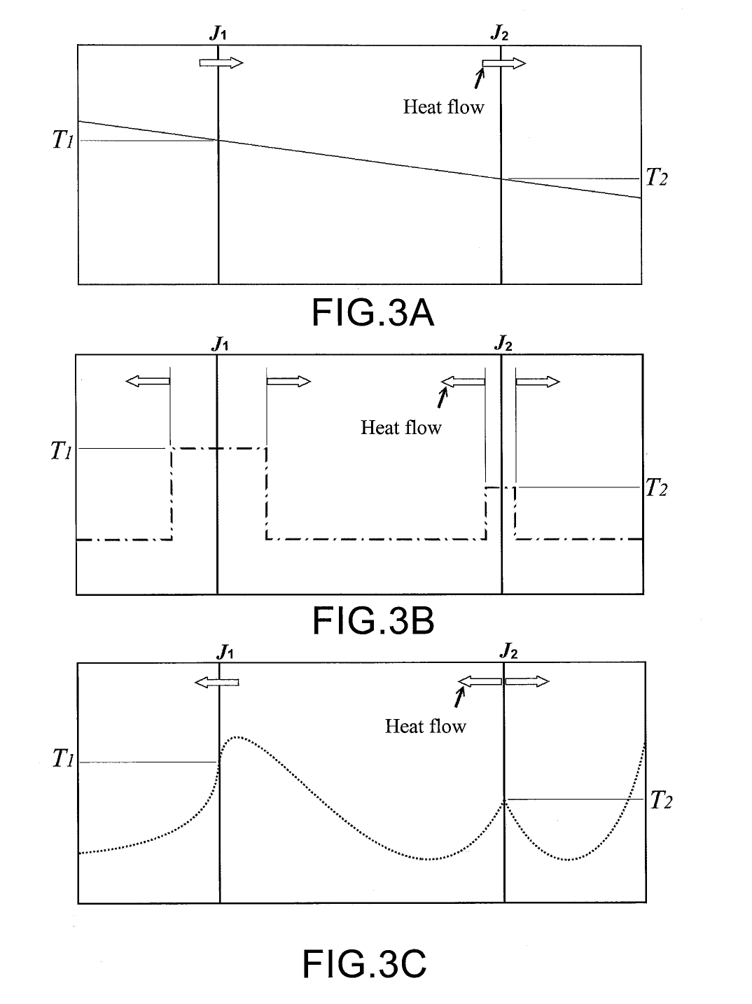

In an experiment, parameters such as heating methods, the amount of heat, and the direction of thermal conduction are varied, and the corresponding results are measured. For example, the temperature variance shown in FIG. 3A is linear; the heating method of FIG. 3B results in a uniform temperature distribution near the junction interfaces J₁ and J₂, but the temperature of regions away from the junction interfaces J₁ and J₁ drops abruptly; the heating method of FIG. 3C renders a nonlinear temperature variance. It is found that regardless of the heating conditions, the output voltage and current are fixed if the resulting temperatures of the junction interfaces J₁ and J₂ are kept at T₁ and T₂.

From these experiments, it is known that the thermoelectric generation occurs primarily at the junction interface of materials and depends upon the local temperature of the junction interface. This is different from the traditional theory which indicates the diffusion or drift of the carrier is caused by the temperature gradient inside the materials.

In other words, the thermoelectric effect actually occurs at the junction interface. The thermoelectric effect would not occur if the heat is supplied to the materials but the junction interface thereof is not affected by heat. When the junction interface is heated, an output voltage is generated as a function of temperature, and the generated current is a function of both the temperature and the area of the junction interface.

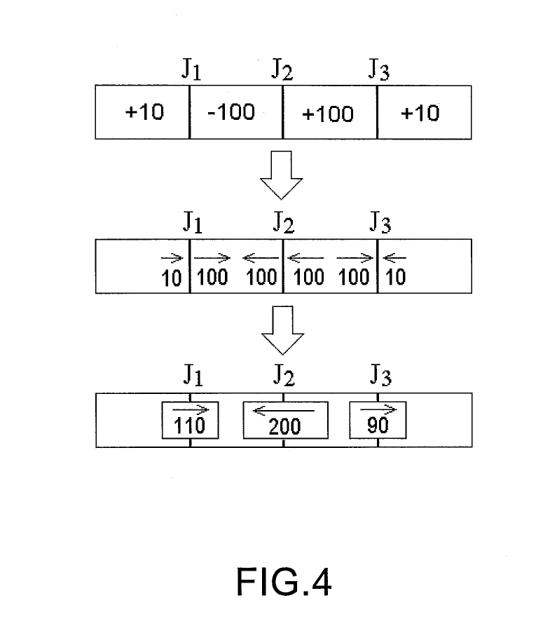

The process and principle of thermoelectric generation is further explained by way of example in FIG. 4. In the upper part of FIG. 4, the material marked with +10 is a metal conductor connected to the thermoelectric material, and the value of the Seebeck effect thereof is +10. Similarly, the material marked with −100 is a thermoelectric material of which the value of the Seebeck effect is −100; the material marked with +100 is a thermoelectric material of which the value of the Seebeck effect is +100. The junction interfaces J₁, J₂, and J₃ between each materials are the reference points (planes) of which the values of Seebeck effect are zero.

If J₁, J₂, and J₃ are in an environment with uniform temperature, electrical generation occurs within each materials and junction interfaces, as shown in the middle of the FIG. 4. That is, with respect to J₁, 10 units of rightward voltage are produced by the material marked with +10, and 100 units of rightward voltage are produced by the material marked with −100; with respect to J₂, 100 units of leftward voltage are produced by the material marked with −100, and 100 units of leftward voltage are produced by the material marked with +100; with respect to J₃, 100 units of rightward voltage are produced by the material marked with +100, and 10 units of leftward voltage are produced by the material marked with +10.

The overall effect of the electrical generation at these junction interfaces is shown in the lower part of FIG. 4, i.e. there are 110 units of rightward voltage at J₁, 200 units of leftward voltage at J₂, and 90 units of rightward voltage at J₃. Therefore, if J₂ is regarded as a positive junction with 200 units of voltage, J₁ is a negative junction with −110 units of voltage, and J₃ a negative junction with −90 units of voltage. At the same temperature, voltages produce at these three junction interfaces cancel out each other, and the output voltage is zero.

Accordingly, in the design of power generation, it is desirable to arrange J₂ with large area and in high temperature environment to maximize the positive power output, and arrange J₃ and J₁ with less area and lower temperature to minimize the counteracting negative power output.

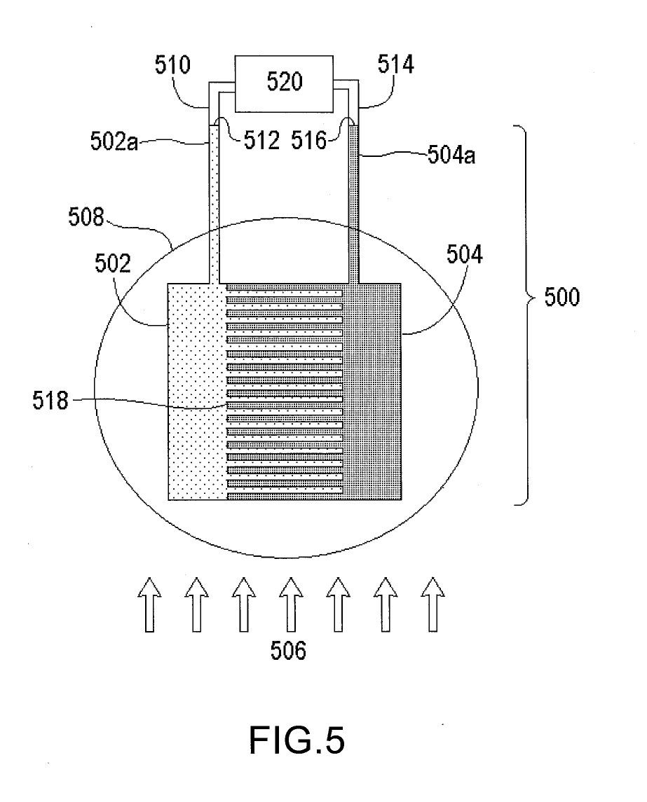

According to the principle of thermoelectric generation disclosed above, i.e. the power generation occurs mainly at the junction interface, the first embodiment of the disclosure provides a thermoelectric generating apparatus, of which a sectional view is shown in FIG. 5.

In FIG. 5, a thermoelectric generating apparatus 500 includes a first thermoelectric device 502 and a second thermoelectric device 504, wherein the Seebeck coefficient of the first thermoelectric device 502 is larger than that of the second thermoelectric device 504. The first thermoelectric device 502 includes a first extended portion 502a, and the second thermoelectric device 504 includes a second extended portion 504a. The first thermoelectric device 502 and the second thermoelectric device 504 are settled in a heating region 508 while being heated by a heat source 506. Outside of the heating region 508, the first extended portion 502a is electrically connected to a first power output end 510 such that a first contact interface 512 is formed therebetween, and the second extended portion 504a is electrically connected to a second power output end 514 so as to form a second contact interface 516. The first thermoelectric device 502 forms an electrical junction interface 518 with the second thermoelectric device 504, wherein the electrical junction interface 518 is an interdigitated junction interface. The area of the electrical junction interface 518 is larger than that of the first contact interface 512 and larger than that of the second contact interface 516 as well. The amount of current generation and the overall power generation are enhanced by the increase of the area of the electrical junction interface 518. The area of the electrical junction interface 518 may be increased by the micro electro mechanical process, microstructure process, or nano-processing.

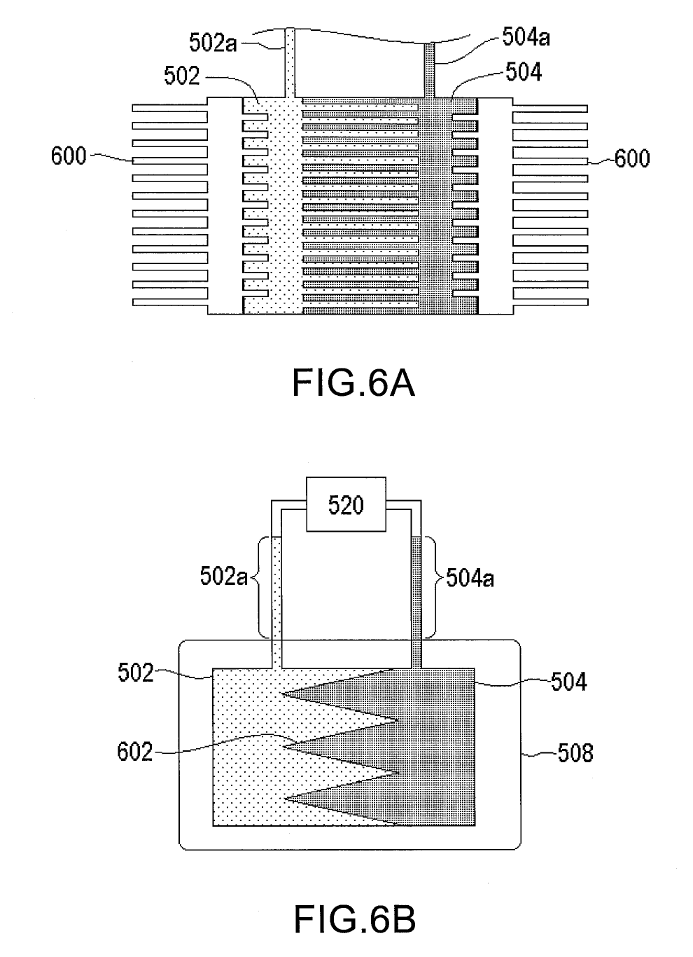

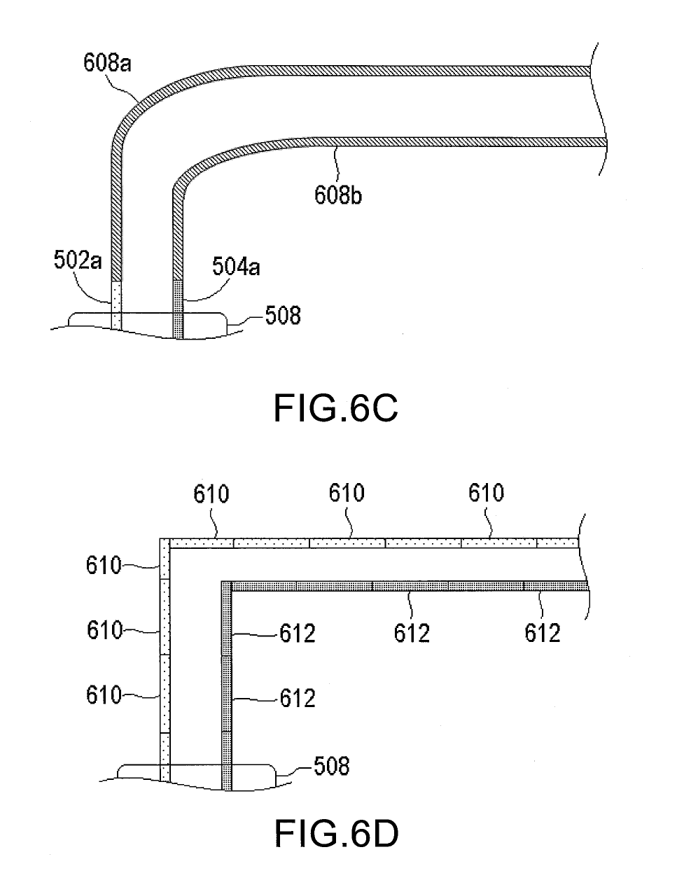

When heat is supplied to the electrical junction interface 518 by the heat source, electrical power is generated by the thermoelectric generating apparatus 500, provided that the temperature of the electrical junction interface 518 is higher than that of the first and second contact interfaces 512 and 516. The electrical power is output by the first power output end 510 and the second power output end 514, which are connected to an external circuit 520. Further, when heated by the heat source 506, the electrical junction interface 518 may have a non-linear heat distribution. It is not necessary to precisely control the temperature of the cold and hot ends as the conventional thermoelectric generating apparatuses do. Of course the heat distribution of the electrical junction interface 518 may also be linear. Heating by the heat source 506 may be carried out by attaching a heater to the electrical junction interface 518 and raising the temperature thereof by thermal conduction. Also, heating by the heat source 506 may be carried out by immersing the first and second thermoelectric devices 502 and 504 into a heat source system, e.g. a heat bath, to absorb heat under the condition that the first and second contact interfaces 512 and 516 are in no contact with the heat source system. A heat spreader 600 as shown in FIG. 6A may be attached to or embedded in the periphery of the first and second contact interfaces 512 and 516 to facilitate the thermal conduction without changing the electric circuit. The heat source 506 may also be geotherm, solar energy, industrial waste heat, waste heat from home appliances, or waste heat from vehicles, etc. In present embodiment, the first and second thermoelectric devices 502 and 504 may include materials listed in Table 1.

TABLE 1

| | Seebeck coefficient |
|---|---|
| Material | (μV/K) |
| antimony | 47 |
| Nichrome | 25 |
| molybdenum | 10 |
| cadmium | 7.5 |
| tungsten | 7.5 |
| golf | 6.5 |
| silver | 6.5 |
| copper | 6.5 |
| rhodium | 6.0 |
| tantalum | 4.5 |
| lead | 4.0 |
| aluminum | 3.5 |
| carbon | 3.0 |
| mercury | 0.6 |
| platinum | 0 |
| sodium | −2.0 |
| potassium | −9.0 |
| nickel | −15 |
| Constantan | −35 |
| bismuth | −72 |
| CeFe₄Sb₁₂ | 154 |
| CoSb₃ | −153 |
| selenium | 900 |
| tellurium | 500 |
| silicon | 440 |
| germanium | 300 |
| n-type Bi₂Te₃ | −230 |
| p-type Bi₂₋ₓSbₓTe₃ | 300 |
| p-type Sb₂Te₃ | 185 |
| PbTe | −180 |
| Pb₀₃Ge₃₉Se₅₈ | 1670 |
| Pb₀₆Ge₃₆Se₅₈ | 1410 |
| Pb₀₉Ge₃₃Se₅₈ | −1360 |
| Pb₁₃Ge₂₉Se₅₈ | −1710 |
| Pb₁₅Ge₃₇Se₅₈ | −1990 |
| SnSb₄Te₇ | 25 |
| SnBi₄Te₇ | 120 |
| SnBi₃Sb₁Te₇ | 151 |
| SnBi_{2.5}Sb_{1.5}Te₇ | 110 |
| SnBi₂Sb₂Te₇ | 90 |
| PbBi₄Te₇ | −53 |
| iron | 19 |
| Zn₄Sb₃ | 165 |

Furthermore, the first and second thermoelectric devices 502 and 504 are shown as grating structures in FIG. 5, and are jointed to form an interdigitated junction interface (i.e. the electrical junction interface 518) with increased contact area. The present embodiment, however, is not limited thereto. The electrical junction interfaces 518 may be any kind of interdigitated junction interfaces. For example, the electrical junction interface shown in FIG. 6B is a zigzag interface 602.

In the first embodiment, the first and second extended portion 502a and 504a are linear structures which may not only substantially reduce the thermal resistivity but, by regulating the relationship between the thermal resistivity and electrical conductivity, minimize the power loss as the heat conducted to the first and second contact interfaces 512 and 516 is reduced. If the first and second extended portion 502a and 504a are well insulated, the heat loss may be reduced and the power generation efficiency may be enhanced. The first and second extended portion 502a and 504a extend into an environment with lower temperature and connect to other materials or circuit elements with the first and second contact interfaces 512 and 516. This ensures the first and second contact interfaces 512 and 516 are located in an environment with lower temperature, and thus the counteracting power generation is reduced. Therefore, the temperature of the first and second contact interfaces 512 and 516 is preferably lower as compared to the heat source 506. In another embodiment, a cooling device (not shown) may be constructed to cool the first and second contact interfaces 512 and 516, or a thermal insulating device (not shown) may be adopted to insulate the heat from the heat source 506 from transferring to the first and second contact interfaces 512 and 516. For example, the first contact interfaces 512 may be covered by a thermal insulating film.

Referring FIG. 5, if the first power output end 510 and the second power output end 514 between the thermoelectric generating apparatus 500 and the external circuit 520 are made of flexible materials, the shape thereof may be changed with the working environment. As shown in FIG. 6C, outside of the heating region 508, electrical leads 608a and 608b is connected to the first and second extended portion 502a and 504a. In general, electrical leads have some flexibility and may be variously treated depending on the application environment and conditions. The application scope of the disclosure is thus substantially widened. A material with electrical or thermal insulating properties may be covered on the surfaces of electrical leads 608a and 608b.

In addition, the first and second extended portions may be formed as structures with a plurality of segments. As shown in FIG. 6D, the first extended portion 610 and the second extended portion 612 are linear structures including a plurality of segments, and are preferably made of the same materials as the first and second thermoelectric devices 502 and 504, respectively.

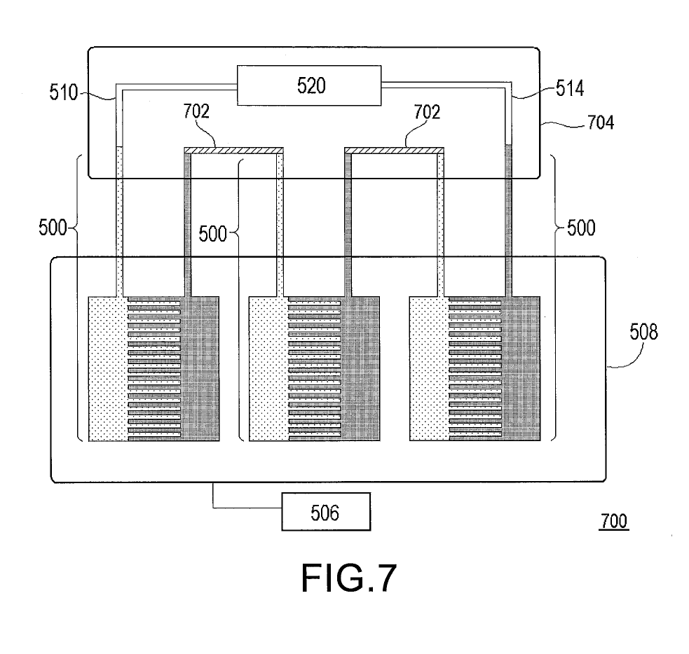

FIG. 7 is a schematic diagram of a thermoelectric generating module according to the second embodiment of the disclosure, wherein the same reference numerals refer to the same or similar elements with respect to FIG. 5.

In the second embodiment, the thermoelectric generating module 700 regulates the ratio of voltage to output value by connecting each thermoelectric generating apparatus 500 in series, e.g. the thermoelectric generating apparatuses 500 is connected by electrical leads 702. Thermoelectric generation may be easily accomplished by placing the contact interfaces of thermoelectric generating apparatus 500 and other materials such as the first power output end 510, the second power output end 514, and electrical leads 702 in a low temperature region 704.

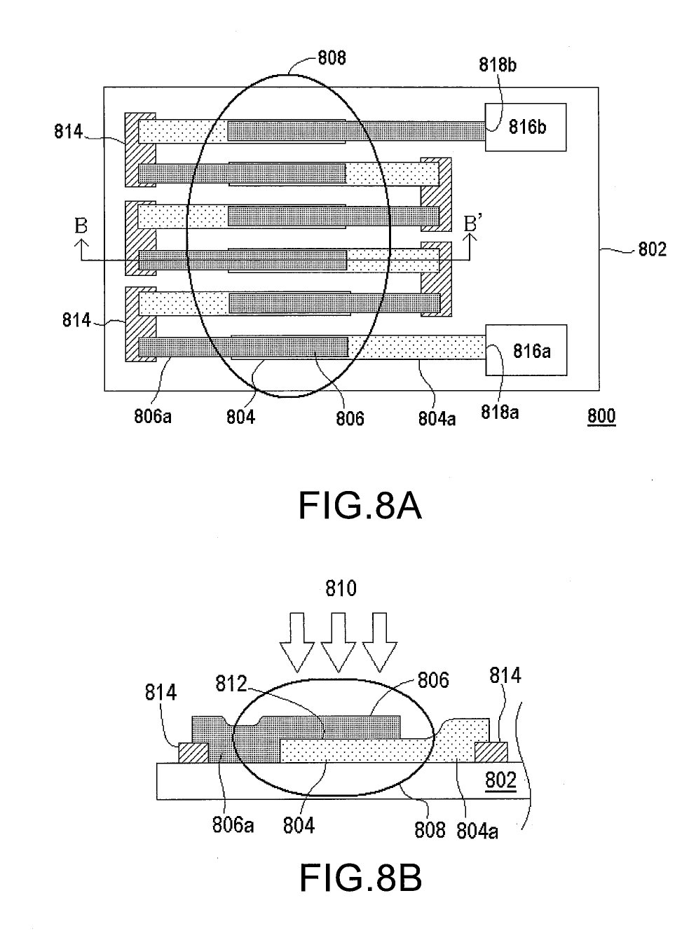

FIG. 8A is a top view of a thermoelectric generating apparatus according to the third embodiment of the disclosure. FIG. 8B is a sectional view along the line B-B′ in FIG. 8A.

Referring to FIGS. 8A and 8B, a thermoelectric generating apparatus 800 according to the third embodiment is fabricated on a substrate 802 and includes first thermoelectric devices 804 and second thermoelectric devices 806. A heat source 810 is disposed above the thermoelectric generating apparatus 800; the heating region 808 of the heat source 810 is also shown in FIG. 8B. The first thermoelectric device 804 forms an electrical junction interface 812 with the second thermoelectric device 806. The Seebeck coefficient of the first thermoelectric device 804 is larger than that of the second thermoelectric device 806. Outside of the heating region 808, the first extended portion 804a of the first thermoelectric device 804 is connected in series to the second extended portion 806a of the second thermoelectric device 806 by a conductive layer 814. Referring to FIG. 8A, the first extended portion 804a of the lower most first thermoelectric device 804 is electrically connected to the first power output end 816a such that a contact interface 818a is formed therebetween, and the second extended portion 806a of the upper most second thermoelectric device 806 is electrically connected to the second power output end 816b such that a contact interface 818b is formed therebetween. The area of the electrical junction interface 812 is larger than that of the contact interface 818a and larger than that of the contact interface 818b as well. The principle of power generation of the third embodiment is the same as that of embodiments described above. In the present embodiment, however, the first and second extended portions 804a and 806a are in similar size to the first and second thermoelectric devices 804 and 806.

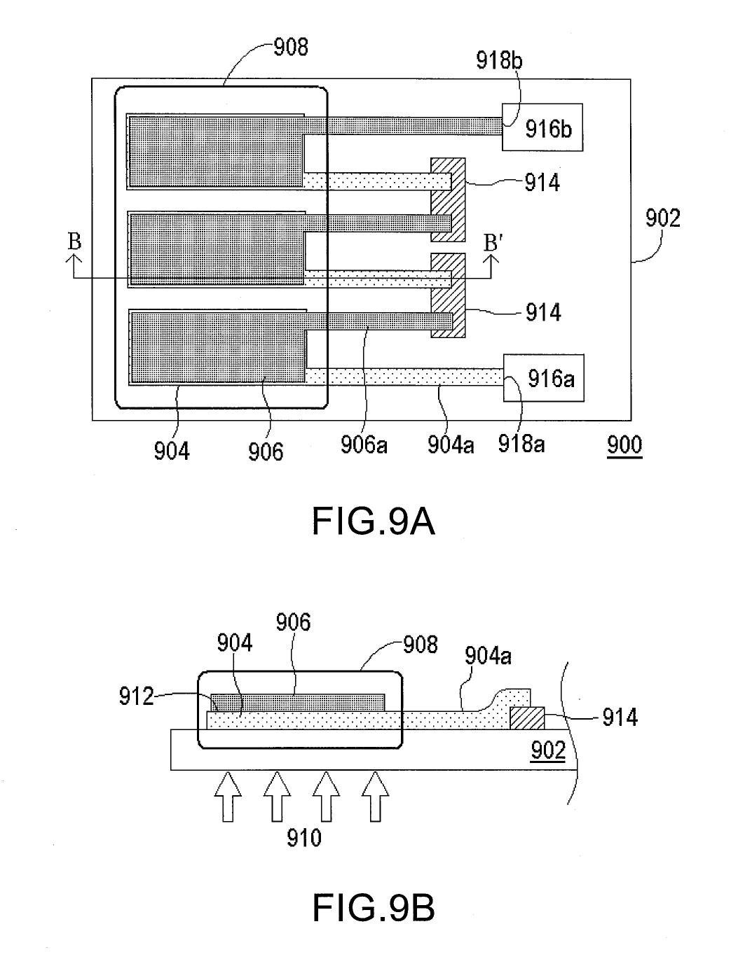

FIG. 9A is a top view of a thermoelectric generating apparatus according to the fourth embodiment of the disclosure. FIG. 9B is a sectional view along the line B-B′ in FIG. 9A.

Referring to FIGS. 9A and 9B, a thermoelectric generating apparatus 900 according to the fourth embodiment is fabricated on a substrate 902 and includes first thermoelectric devices 904 and second thermoelectric devices 906. A heat source 910 is disposed under the thermoelectric generating apparatus 900; the heating region 908 of the heat source 910 is also shown in FIG. 9B. The first thermoelectric device 904 forms an electrical junction interface 912 with the second thermoelectric device 906. The Seebeck coefficient of the first thermoelectric device 904 is larger than that of the second thermoelectric device 906. Outside of the heating region 908, the first extended portion 904a of the first thermoelectric device 904 is connected in series to the second extended portion 906a of the second thermoelectric device 906 by a conductive layer 914. Referring to FIG. 9A, the first extended portion 904a of the lower most first thermoelectric device 904 is electrically connected to the first power output end 916a such that a contact interface 918a is formed therebetween, and the second extended portion 906a of the upper most second thermoelectric device 906 is electrically connected to the second power output end 916b such that a contact interface 918b is formed therebetween. The area of the electrical junction interface 912 is larger than that of the contact interface 918a and also larger than that of the contact interface 918b. The principle of power generation of the fourth embodiment is the same as that of embodiments described above; other features of the fourth embodiment may also be referred to the first embodiment.

Structures of embodiments described above have several unprecedented properties.

1. The larger the area of the electrical junction interface between the first and the second thermoelectric devices, the higher the power generation efficiency. As a result, the power generation efficiency may be easily enhanced.

2. If the first and second extended portions are thin and long structures, a good conductivity and a low thermal conductivity may be simultaneously achieved. The thermal resistance between the heat source and the low temperature environment become considerable, so the heat loss is substantially reduced. At the same time, the power generated solely inside of the heat source system may be readily harnessed and exploited from the external environment. As a result, the heat loss ratio may be greatly reduced and the power generation efficiency is promoted.

3. The thermoelectric generating apparatus according to the disclosure is not limited to the concept of “cold end dissipation” as some of the conventional thermoelectric generating apparatuses do. In other words, the mechanism of cooling the first and second contact interfaces between the extended portions and the power output ends by a cooling device is no longer necessary. The disclosure therefore has unprecedented advantages in a number of aspects such as the facility of application, the cost, the reduction of heat loss, the enhancement of the efficiency, the technical threshold, the volume of the thermoelectric generating apparatus, and the environmental limit.

4. Some of the conventional thermoelectric generator requires heat dissipation at the cold end; the heat from the heat source is dissipated to the air and greatly wasted, and as a consequence the power generation efficiency is low. In the contrary, the entire module structure according to the disclosure requires only a heat source to generate electrical power, and the conventional active cooling system may be omitted. The thermoelectric generating apparatus according to the disclosure on the one hand may keep the temperature difference between the cold end and the hot end, on the other hand may substantially restrain the heat from transferring from the hot end to the cold end and dissipating to the air.

5. With regard to the heating method, unlike some of the conventional structures which are heated by attaching one of their surfaces to a plane of heat source, the thermoelectric generating apparatus according the disclosure may be heated by placing the entire volumes of the first and second thermoelectric devices into a heat source system. The breakthrough in application is significant.

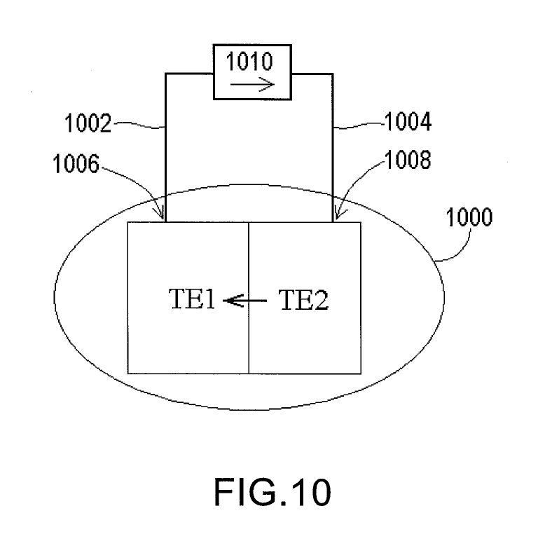

Moreover, the thermoelectric generating apparatus according to the disclosure may be equipped with a compensating thermoelectric structure to establish a compensating voltage forward to the current at the electrical junction interface. The equivalent circuit of such a thermoelectric generating apparatus is shown in FIG. 10 When the heating region 1000 of a heat source includes not only the electrical junction interface between the first and second thermoelectric devices TE1 and TE2 but also the contact interfaces 1006, 1008 between TE1, TE2 and output circuits of other materials 1002, 1004, it is necessary to arrange a compensating thermoelectric structure 1010 to compensate the negative voltage, i.e. negative junction, of the contact interfaces 1006, 1008. The following are embodiments of the thermoelectric generating apparatuses equipped with different types of compensating thermoelectric structures.

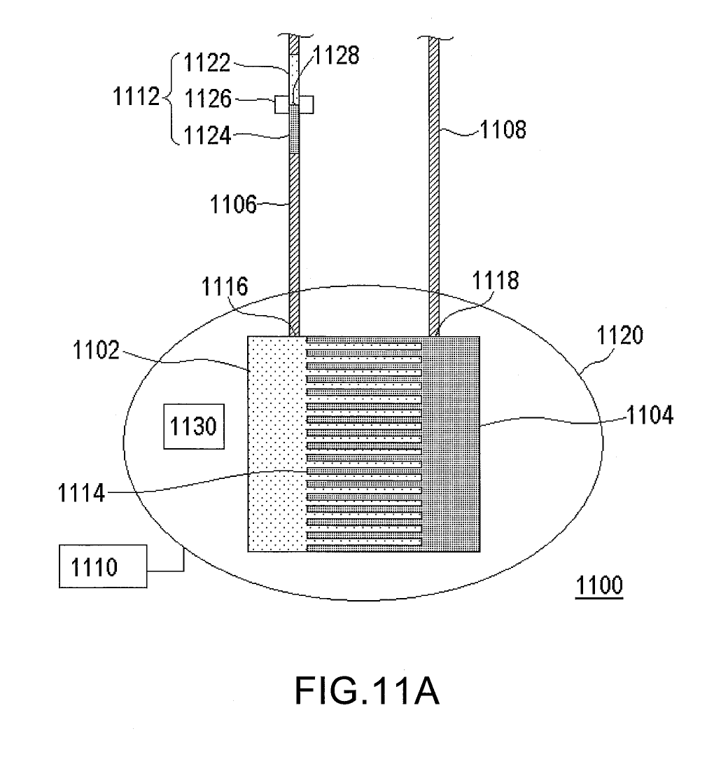

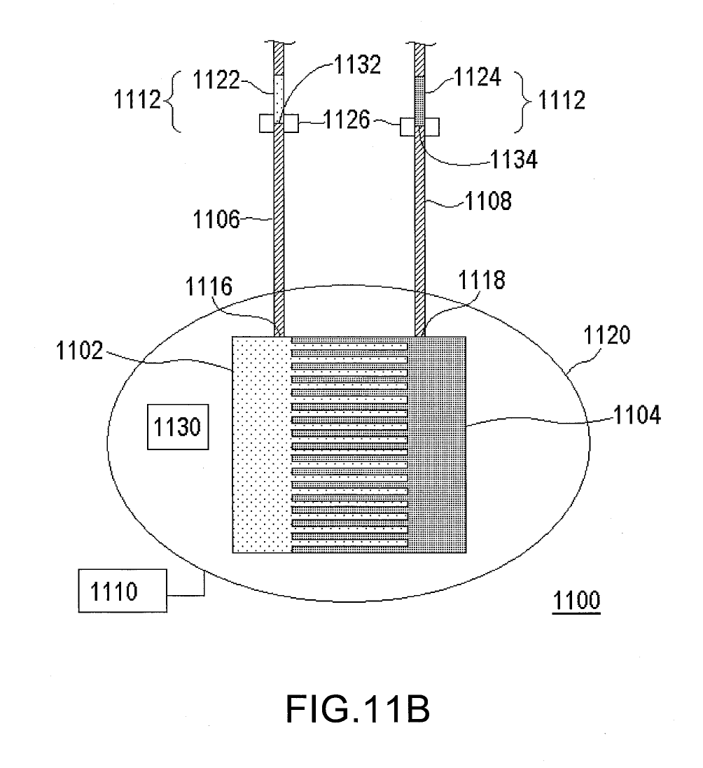

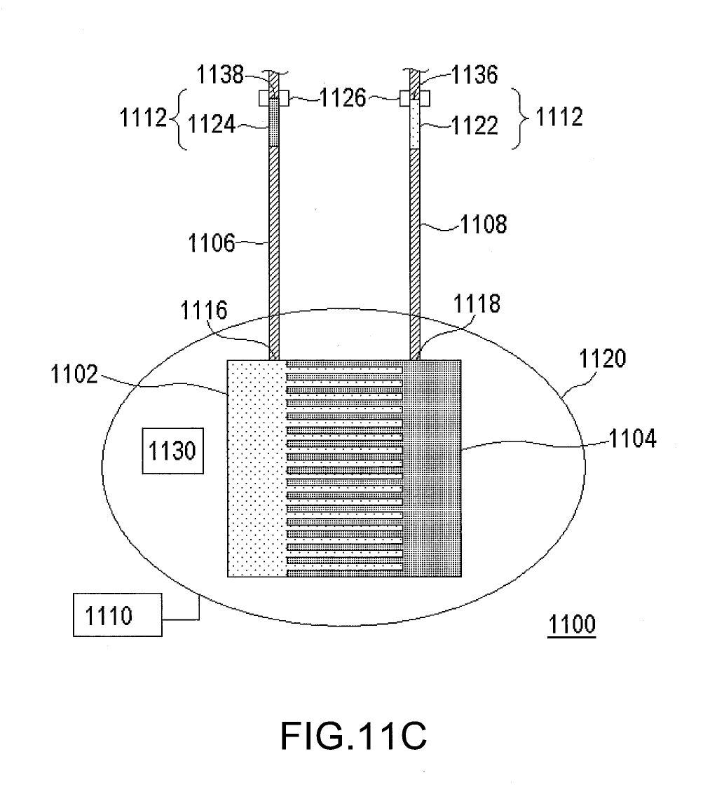

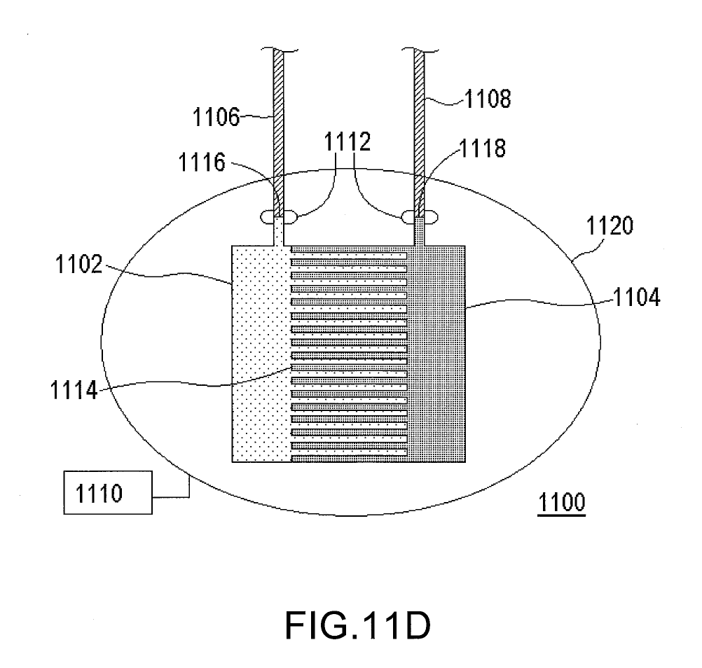

FIG. 11A is a sectional view of the first type of the thermoelectric generating apparatus according to the fifth embodiment of the disclosure.

Referring to FIG. 11A, the thermoelectric generating apparatus 1100 includes a first thermoelectric device 1102, a second thermoelectric device 1104, a first output circuit 1106, a second output circuit 1108, and a compensating thermoelectric structure 1112. A first heat source 1110 is arranged outside of the thermoelectric generating apparatus 1100 to supply heat so that the first electrical junction interface 1114 between the first and second thermoelectric devices 1102 and 1104 is located in a heating region 1120. The Seebeck coefficient of the first thermoelectric device 1102 is larger than that of the second thermoelectric device 1104. The first output circuit 1106 is connected to the first thermoelectric device 1102 such that a first contact interface 1116 is formed therebetween. The second output circuit 1108 is connected to the second thermoelectric device 1104 such that a second contact interface 1118 is formed therebetween. Both the first contact interface 1116 and the second contact interface 1118 are located in the heating region 1120. The area of the first electrical junction interface 1114 is larger than that of the first contact interface 1116 and also larger than that of the second contact interface 1118. For example, the first electrical junction interface may be an interdigitated junction interface, and therefore the contact area thereof may be larger than the area of the first contact interface 1116 and larger than the area of the second contact interface 1118 as well. As shown in this figure, the first electrical junction interface 1114 may be a grating pattern junction surface, but the disclosure is not limited thereto. The first electrical junction interface 1114 may be a zigzag pattern junction surface as well.

Since the first electrical junction interface 1114, the first contact interface 1116, and the second contact interface 1118 are located in the heating region 1120, the compensating thermoelectric structure including a first compensating thermoelectric device 1122 and a second compensating thermoelectric device 1124 are disposed outside of the heating region 1120 of the first heat source 1110 according to the disclosure. The second compensating thermoelectric device 1124 is connected to the first output circuit 1106 at one end and to the first compensating thermoelectric device 1122 at the other. A second electrical junction interface 1228 formed between the first and second compensating thermoelectric devices 1122 and 1124 is heated by a second heat source 1126. The Seebeck coefficient of the first compensating thermoelectric device 1122 is larger than that of the second compensating thermoelectric device 1124. The area of the second electrical junction interface 1128 is larger than that of the first contact interface 1116. Heated by the second heat source 1126, the temperature of the second electrical junction interface 1128 is larger than or equal to that of the first contact interface 1116. A compensating voltage forward to the current at the first electrical junction interface 1114 and reverse to the current at the first contact interface 1116 is therefore produced. In this figure, heating by the second heat source 1126 may be adjusted according to a temperature sensor 1130 located in the heating region 1120 of the first heat source 1110. The heat distribution of the first electrical junction interface 1114 may be linear or nonlinear.

Further, the first and second thermoelectric devices 1102 and 1104 of the fifth embodiment may be connected to each other by a conductive layer. This may be referred to the third or the fourth embodiments, and the details are therefore omitted here.

FIG. 11B is a sectional view of the second type of the thermoelectric generating apparatus according to the fifth embodiment of the disclosure, wherein the same reference numerals refer to the same or similar elements with respect to FIG. 11A.

Referring to FIG. 11B, a first compensating thermoelectric device 1122 of a compensating thermoelectric structure 1112 is connected to a first output circuit 1106 such that a third contact interface 1132 is formed at an end of the first compensating thermoelectric device 1122 closer to the first contact interface 1116. A second compensating thermoelectric device 1124 is connected to a second output circuit 1108 such that a fourth contact interface 1134 is formed at an end of the second compensating thermoelectric device 1124 closer to the second contact interface 1118. The third and fourth contact interfaces 1132 and 1134 are heated by the second heat source 1126 so that the temperature of the third and fourth contact interfaces 1132 and 1134 is larger than that of the first and second contact interfaces 1116 and 1118.

FIG. 11C is a sectional view of the third type of the thermoelectric generating apparatus according to the fifth embodiment of the disclosure, wherein the same reference numerals refer to the same or similar elements with respect to FIG. 11A.

Referring to FIG. 11C, a first compensating thermoelectric device 1122 of a compensating thermoelectric structure 1112 is connected to a second output circuit 1108 such that a fifth contact interface 1136 is formed at an end of the first compensating thermoelectric device 1122 away from the second contact interface 1118. A second compensating thermoelectric device 1124 is connected to a first output circuit 1106 such that a sixth contact interface 1138 is formed at an end of the second compensating thermoelectric device 1124 away from the first contact interface 1116. The fifth and sixth contact interfaces 1136 and 1138 are heated by the second heat source 1126 so that the temperature of the fifth and sixth contact interfaces 1136 and 1138 is larger than that of the first and second contact interfaces 1116 and 1118.

In FIGS. 11A to 11C, the material of the first compensating thermoelectric device 1122 and that of the first thermoelectric device 1102 may be the same or different, preferably the same. The material of the second compensating thermoelectric device 1124 and that of the second thermoelectric device 1104 may be the same of different, preferably the same. The second heat source 1126 is not particularly limited. For example, it may be heating fins, geotherm, solar energy, industrial waste heat, waste heat from home appliances, or waste heat from vehicles, etc.

FIG. 11D is a sectional view of the fourth type of the thermoelectric generating apparatus according to the fifth embodiment of the disclosure, wherein the same reference numerals refer to the same or similar elements with respect to FIG. 11A.

Referring to FIG. 11D, the compensating thermoelectric structure 1112 may be a cooling device which lowers the temperature of the first contact interface 1116 and the second contact interface 1118, but does not affect the temperature of the first electrical junction interface 1114. The compensating thermoelectric structure 1112 may also be a thermal insulating device which insulates the heat from the first heat source 1110 from transferring to the first and second contact interfaces 1116 and 1118.

In the fifth embodiment, the first electrical junction interface 1114 is heated by the first heat source 1110, and the heat distribution may be referred to the first embodiment. The jointing manner of the first thermoelectric device 1102 and the second thermoelectric device 1104 and shape of the first electrical junction interface 1114 may also be referred to the first embodiment.

The thermoelectric generating apparatus 1100 according to the fifth embodiment may be connected in series to regulate the ratio of voltage to output value; for example, a thermoelectric generating module may be formed by connecting individual thermoelectric generating apparatus 1100 by electrical leads, as shown in FIG. 7.

To verify the effect of the disclosure, a simulation result is presented in the following.

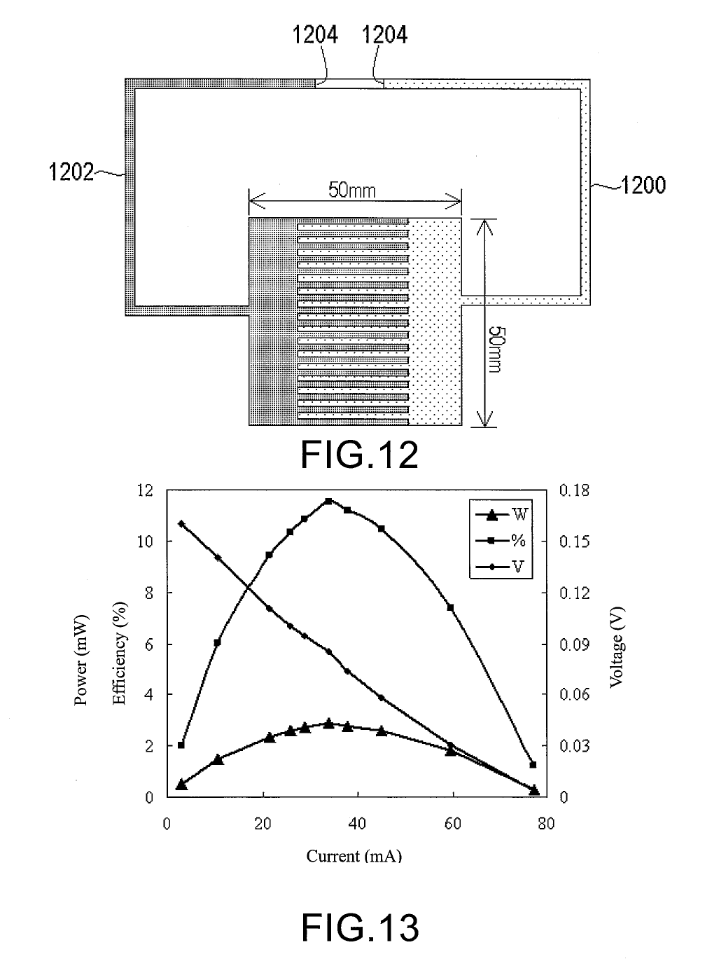

First, as shown in FIG. 12, a thermoelectric generating apparatus is constructed based on the principle of the first embodiment that power generation occurs at the junction interface. The thermoelectric materials 1200 and 1202 are compounds of Bi₂Te₃; the thermal conductivity coefficient and the resistivity thereof are 1.6 w/m·K and 1×10⁻⁵ ohm·m, respectively. The Seebeck coefficient of the p-doped material 1200 is 210 μV/k, and the Seebeck coefficient of the n-doped material 1202 is −210 μV/k. The p-doped material 1200 and n-doped material 1202 are jointed to form fifty stacked positive junction interfaces. The positive junction interface portion is a cube of 50 mm×50 mm×50 mm. Along the direction parallel to the positive junction interfaces, one end (in FIG. 12, the left end) of the positive junction interface portion is connected to an n-type thermoelectric material; the other end (in FIG. 12, the right end) is connected to a p-type thermoelectric material. In this way, the current flows along the direction parallel to the positive junction interfaces. The result is equivalent to a single junction interface constituted by fifty positive junction interfaces, wherein the single junction interface is perpendicular to the current direction. The extended portions are p-type thermoelectric material and n-type thermoelectric material each with a length of 220 mm and a cross-sectional area of 0.04 mm². The endpoints of the extended portions are connected by a resistor such that a circuit is formed. In the simulation, the entirety of the positive junction interface portion is set to be heated; the surfaces of the positive junction interface portion and the extended portion are set to be heat-insulated; the coefficient of heat convection of the surface of the resistor 1204 (i.e. where the negative junction forms) is set to be 15 W/m² as natural convection; the environmental temperature is 25° C.

The thermoelectric generating apparatus described above is analyzed by the function of thermoelectric coupling analysis of Ansys software. The calculated result is that, upon 25 mW of input power of heat source, the equilibrium temperature is 304° C. at the positive junction interface (i.e. the hot end) and 27.8° C. at the resistor 1204 (i.e. the cold end). The electrical characteristic curves are shown in FIG. 13. The open circuit voltage is 0.17 V, the short circuit current 0.08 A, the maximum output power 2.9 mW, and the conversion efficiency 11.2%.

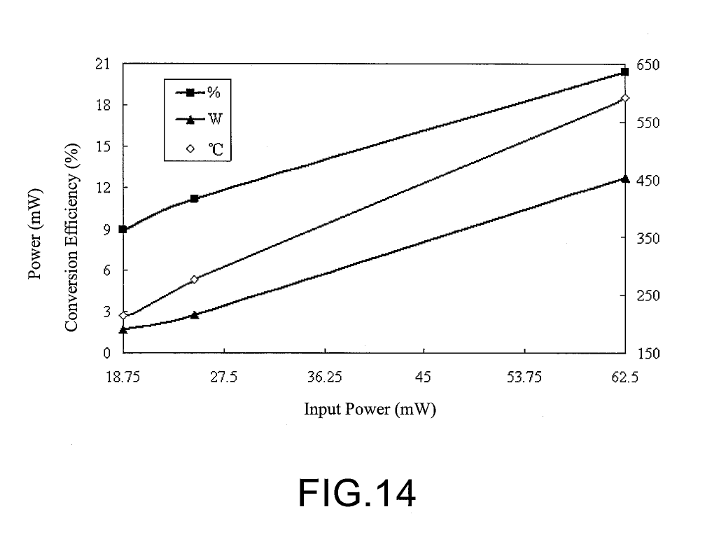

The analysis result of changing the input power of the heat source is shown in FIG. 14. It is shown that, with the apparatus of FIG. 12, the conversion efficiency attains 11% at a temperature difference of 270° C. When the temperature difference is increased to 600° C. by increasing the input power, the conversion efficiency attains as high as 20%.

In sum, in this disclosure, the cold end and the hot end are separated away to preclude the problem of conventional thermoelectric generating apparatus that the thermal conductive characteristics of the cold end and the hot end are mutually affected. The heat dissipating device thus may be omitted in the thermoelectric generating apparatus of the disclosure, and the application thereof is facilitated. While a thermoelectric generating module is formed by thermoelectric materials, the influence of the thermal conductivity coefficient is insignificant. Accordingly, the development of material and promotion of performance may be focused on increasing power factor, which is much easier to achieve. In consequence, the overall power generation efficiency may have great chance to be substantially enhanced. Also, the thermoelectric generating apparatus according to the disclosure may be equipped with a compensating thermoelectric structure, and the application scope is much wider accordingly.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A thermoelectric generating apparatus, comprising:
a first thermoelectric device comprising a first extended portion; and
a second thermoelectric device comprising a second extended portion and having an electrical junction interface with the first thermoelectric device, wherein the electrical junction surface is an interdigitated junction interface and the Seebeck coefficient of the first thermoelectric device is larger than the Seebeck coefficient of the second thermoelectric device;
the first extended portion is electrically connected to a first power output end with a first contact interface formed therebetween, and the area of the electrical junction interface is larger than the area of the first contact interface; and
the second extended portion is electrically connected to a second power output end with a second contact interface formed therebetween, and the area of the electrical junction interface is larger than the area of the second contact interface.

2. The thermoelectric generating apparatus according to claim 1, wherein a heat distribution of the electrical junction interface is linear or nonlinear.

3. The thermoelectric generating apparatus according to claim 1, wherein the interdigitated junction surface comprises a grating pattern junction surface or a zigzag pattern junction surface.

4. The thermoelectric generating apparatus according to claim 1, further comprising a conductive layer, connected to the second thermoelectric device and the first thermoelectric device with the electrical junction interface formed therebetween.

5. The thermoelectric generating apparatus according to claim 1, wherein the first power output end and the second power output end comprise electrical leads.

6. The thermoelectric generating apparatus according to claim 1, wherein the first extended portion and the second extended portion is a linear structure comprising a plurality of segments.

7. The thermoelectric generating apparatus according to claim 1, further comprising a cooling device configured to cool a temperature of the first contact interface and a temperature of the second contact interface.

8. The thermoelectric generating apparatus according to claim 1, further comprising a thermal insulating device configured to prevent heat of a heat source from transferring to the first contact interface and the second contact interface.

9. The thermoelectric generating apparatus according to claim 8, wherein the thermal insulating device comprises a thermal insulating film covering the first contact interface and the second contact interface.

10. The thermoelectric generating apparatus according to claim 8, wherein the heat source comprises a heater, geotherm, solar energy, industrial waste heat, waste heat from home appliances, or waste heat from vehicles.

11. The thermoelectric generating apparatus according to claim 8, wherein a temperature of the first contact interface is lower than a temperature of the heat source.

12. The thermoelectric generating apparatus according to claim 8, wherein a temperature of the second contact interface is lower than a temperature of the heat source.

13. A thermoelectric generating module, comprises a plurality of the thermoelectric generating apparatuses according to claim 1.

14. A thermoelectric generating apparatus, comprising:
a first thermoelectric device;
a second thermoelectric device having a first electrical junction interface with the first thermoelectric device, wherein the Seebeck coefficient of the first thermoelectric device is larger than the Seebeck coefficient of the second thermoelectric device;
a first output circuit, which is connected to the first thermoelectric device with a first contact interface formed therebetween, wherein the area of the first electrical junction interface is larger than the area of the first contact interface;
a second output circuit, which is connected to the second thermoelectric device with a second contact interface formed therebetween, wherein the area of the first electrical junction interface is larger than the area of the second contact interface; and
at least one compensating thermoelectric structure, disposed between the first output circuit and the second output circuit.

15. The thermoelectric generating apparatus according to claim 14, wherein a heat distribution of the first electrical junction interface is linear or nonlinear.

16. The thermoelectric generating apparatus according to claim 14, wherein the first electrical junction interface comprises a grating pattern junction surface, a zigzag pattern junction surface, and a flat surface.

17. The thermoelectric generating apparatus according to claim 14, further comprising a conductive layer, connected to the second thermoelectric device and the first thermoelectric device with the first electrical junction interface formed therebetween.

18. The thermoelectric generating apparatus according to claim 14, wherein the first electrical junction interface is an interdigitated junction interface.

19. The thermoelectric generating apparatus according to claim 14, wherein the compensating thermoelectric structure comprises a cooling device configured to cool a temperature of the first contact interface and a temperature of the second contact interface.

20. The thermoelectric generating apparatus according to claim 14, wherein the compensating thermoelectric structure comprises a thermal insulating device configured to prevent heat from a first heat source from transferring to the first contact interface and the second contact interface.

21. The thermoelectric generating apparatus according to claim 14, wherein the compensating thermoelectric structure comprises:
a first compensating thermoelectric device; and
a second compensating thermoelectric device, connected to the first output circuit and the first compensating thermoelectric device with a second electrical junction interface formed therebetween, wherein the Seebeck coefficient of the first compensating thermoelectric device is larger than the Seebeck coefficient of the second compensating thermoelectric device, wherein the area of the second electrical junction interface is larger than or equal to the area of the first contact interface.

22. The thermoelectric generating apparatus according to claim 14, wherein the compensating thermoelectric structure comprises:
a first compensating thermoelectric device, connected to the first output circuit with a third contact interface formed at an end of the first compensating thermoelectric device closer to the first contact interface; and
a second compensating thermoelectric device, connected to the second output circuit with a fourth contact interface formed at an end of the second compensating thermoelectric device closer to the second contact interface, wherein the Seebeck coefficient of the first compensating thermoelectric device is larger than the Seebeck coefficient of the second compensating thermoelectric device.

23. The thermoelectric generating apparatus according to claim 14, wherein the compensating thermoelectric structure comprises:
a first compensating thermoelectric device, connected to the second output circuit with a fifth contact interface formed at an end of the first compensating thermoelectric device away from the second contact interface; and
a second compensating thermoelectric device, connected to the first output circuit with a sixth contact interface formed at an end of the second compensating thermoelectric device away from the first contact interface, wherein the Seebeck coefficient of the first compensating thermoelectric device is larger than the Seebeck coefficient of the second compensating thermoelectric device.

24. The thermoelectric generating apparatus according to claim 21, wherein a material of the first compensating thermoelectric device is the same as a material of the first thermoelectric device.

25. The thermoelectric generating apparatus according to claim 22, wherein a material of the first compensating thermoelectric device is the same as a material of the first thermoelectric device.

26. The thermoelectric generating apparatus according to claim 23, wherein a material of the first compensating thermoelectric device is the same as a material of the first thermoelectric device.

27. The thermoelectric generating apparatus according to claim 21, wherein a material of the second compensating thermoelectric device is the same as a material of the second thermoelectric device.

28. The thermoelectric generating apparatus according to claim 22, wherein a material of the second compensating thermoelectric device is the same as a material of the second thermoelectric device.

29. The thermoelectric generating apparatus according to claim 23, wherein a material of the second compensating thermoelectric device is the same as a material of the second thermoelectric device.

30. The thermoelectric generating apparatus according to claim 14, wherein the compensating thermoelectric structure is configured to form a compensating voltage corresponding to a current of the first electrical junction interface.

31. A thermoelectric generating module, which comprises a plurality of the thermoelectric generating apparatuses according to claim 14.
